(19) United States
(12) Patent Application Publication
(10) Pub. No.: US 2026/0164632 A1
(43) Pub. Date: Jun. 11, 2026

(54) MEMORY DEVICE AND MANUFACTURING METHOD THEREOF

(71) Applicant: TAIWAN SEMICONDUCTOR MANUFACTURING COMPANY, LTD., Hsinchu (TW)

(72) Inventors: Jui-Lin CHEN, TAIPEI CITY (TW); Yung-Ting CHANG, New Taipei City (TW); Chih-Ching WANG, Kinmen County (TW)

(73) Assignee: TAIWAN SEMICONDUCTOR MANUFACTURING COMPANY, LTD., Hsinchu (TW)

(21) Appl. No.: 18/970,507

(22) Filed: Dec. 5, 2024

(51) Int. Cl. H10B 10/00

(52) U.S. Cl. CPC H10B 10/125

(57) ABSTRACT

An integrated circuit is provided and includes a first gate structure shared by a first transistor in a first semiconductor level and a second transistor in a second semiconductor level; a first conductive segment shared by a third transistor and a fourth transistor that are disposed in the first semiconductor level; a first connection structure coupling the first gate structure to the first conductive segment on a first side of the integrated circuit; a second gate structure shared by the fourth transistor and a fifth transistor that is disposed in a second semiconductor level; a second connection structure coupled to the second gate structure and disposed on a second side, different from the first side, of the integrated circuit; and a second connection segment corresponding to a first terminal of the second transistor and coupled to the second connection structure.

### BACKGROUND

The integration of contact and metal routing within complementary field-effect transistors (CFETs), a fundamental element of static random-access memory (SRAM), presented a significant design challenge. This complexity originated from the necessity for supplementary mask layers during the fabrication process, a consequence of the intricate nature of the CFET device architecture. Furthermore, the complex geometry of specific routing patterns required the use of extreme ultraviolet (EUV) lithography, a highly sophisticated and intricate fabrication process. The structural constraints imposed by the node-gate connection architecture on the device's reverse side, in addition to those of the routing itself, significantly limited the design flexibility of the latter.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of part of a memory device, in accordance with some embodiments.

FIG. 2A is a layout diagram of a front side of an integrated circuit corresponding to the memory device of FIG. 1, in accordance with some embodiments.

FIG. 2B is a layout diagram of a back side of the integrated circuit corresponding to FIG. 2A, in accordance with some embodiments.

FIG. 2C is a layout diagram of including part of the front side and the back side of the integrated circuit corresponding to FIG. 2A, in accordance with some embodiments.

FIG. 3A is a cross-sectional view of the integrated circuit corresponding to FIGS. 2A and 2B along line AA′, in accordance with some embodiments.

FIG. 3B is a cross-sectional view of the integrated circuit corresponding to FIGS. 2A and 2B along line BB′, in accordance with some embodiments.

FIG. 4A is a layout diagram of a front side of an integrated circuit corresponding to the memory device of FIG. 1, in accordance with some embodiments.

FIG. 4B is a layout diagram of a back side of the integrated circuit corresponding to FIG. 4A, in accordance with some embodiments.

FIG. 5A is a layout diagram of a front side of an integrated circuit corresponding to the memory device of FIG. 1, in accordance with some embodiments.

FIG. 5B is a layout diagram of a back side of the integrated circuit corresponding to FIG. 5A, in accordance with some embodiments.

FIG. 6A to FIG. 6E are cross-sectional diagrams of the integrated circuit corresponding to FIGS. 5A and 5B along lines CC′, DD′, EE′, FF′ and GG′ separately, in accordance with some embodiments.

FIG. 6F is a cross-sectional diagram of the integrated circuit corresponding to FIGS. 5A and 5B, along the line GG′ according to an embodiment different from FIG. 6E.

FIG. 7A is a layout diagram of a front side of an integrated circuit corresponding to the memory device of FIG. 1, in accordance with some embodiments.

FIG. 7B is a layout diagram of a back side of the integrated circuit corresponding to FIG. 7A, in accordance with some embodiments.

FIG. 8 is a flow chart of a method of manufacturing an integrated circuit, in accordance with some embodiments.

FIG. 9 is a block diagram of a system for designing the integrated circuit layout design, in accordance with some embodiments of the present disclosure.

FIG. 10 is a block diagram of an integrated circuit manufacturing system, and an integrated circuit manufacturing flow associated therewith, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

The terms used in this specification generally have their ordinary meanings in the art and in the specific context where each term is used. The use of examples in this specification, including examples of any terms discussed herein, is illustrative only, and in no way limits the scope and meaning of the disclosure or of any exemplified term. Likewise, the present disclosure is not limited to various embodiments given in this specification.

Although the terms “first,” “second,” etc., may be used herein to describe various elements, these elements should not be limited by these terms. These terms are used to distinguish one element from another. For example, a first element could be termed a second element, and, similarly, a second element could be termed a first element, without departing from the scope of the embodiments. As used herein, the term “and/or” includes any and all combinations of one or more of the associated listed items.

As used herein, the terms “comprising,” “including,” “having,” “containing,” “involving,” and the like are to be understood to be open-ended, i.e., to mean including but not limited to.

As used herein, “around”, “about”, “approximately” or “substantially” shall generally refer to any approximate value of a given value or range, in which it is varied depending on various arts in which it pertains, and the scope of which should be accorded with the broadest interpretation understood by the person skilled in the art to which it pertains, so as to encompass all such modifications and similar structures. In some embodiments, it shall generally mean within 20 percent, preferably within 10 percent, and more preferably within 5 percent of a given value or range. Numerical quantities given herein are approximate, meaning that the term “around”, “about”, “approximately” or “substantially” can be inferred if not expressly stated, or meaning other approximate values.

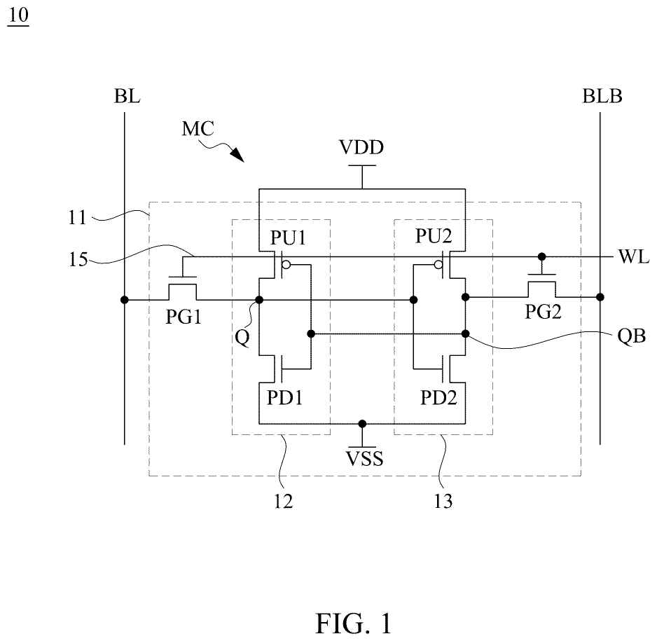

Reference is now made to FIG. 1. FIG. 1 is a schematic diagram of part of a memory device 10, in accordance with some embodiments of the present disclosure. For illustration, a memory cell MC in the memory device 10 is coupled to bit lines BL and BLB.

In some embodiments, the memory cell MC includes an inverter 12 and an inverter 13. The inverter 12 and the inverter 13 are cross-coupled. Effectively, the inverter 12 and the inverter 13 operate as a data latch. For illustration, an output node of the inverter 12 and an input node of the inverter 13 are connected together at a node Q shown in FIG. 1. An input node of the inverter 12 and an output node of the inverter 13 are connected together at a node QB shown in FIG. 1.

For illustration of operation, the data latch, including the inverter 12 and the inverter 13, is able to store a bit of data at the node Q. For illustration, a voltage level on the node Q is able to be configured at different voltage levels. The voltage level of the node Q represents logic “1” or logic “0” corresponding to logic data stored in the memory cell MC. The node QB has a logical level opposite to that of the node Q. For convenience of illustration hereinafter, logic “0” indicates a low level, and logic “1” indicates a high level. The indications are given for illustrative purposes. Various indications are within the contemplated scope of the present disclosure.

In some embodiments, the memory cell MC illustrated in FIG. 1 is a static random-access memory (SRAM) cell, including, for illustration, six transistors PU1-PU2, PD1-PD2 and PG1-PG2. The pull up transistor PU1 and the pull down transistor PD1 are configured and operate as the inverter 12. The pull up transistor PU2 and the pull down transistor PD2 are configured and operate the inverter 13. In some embodiments, the pull down transistors PD1-PD2 and the pass gate transistors PG1-PG2 are N-type transistors, and the pull up transistors PU1-PU2 are P-type transistors.

In some embodiments, the transistor PG1 is configured as a first pass gate transistor, and the transistor PG2 is configured as a second pass gate transistor. For illustration, gate terminals of the transistor PG1 and the transistor PG2 are coupled to a word line and controlled by a word line signal. The output node of the inverter 12 and the input node of the inverter 13, i.e., the node Q, are coupled through the transistor PG1 to the bit line BL. The input node of the inverter 12 and the output node of the inverter 13, i.e., the node QB, are coupled through the transistor PG2 to the complementary bit line BLB.

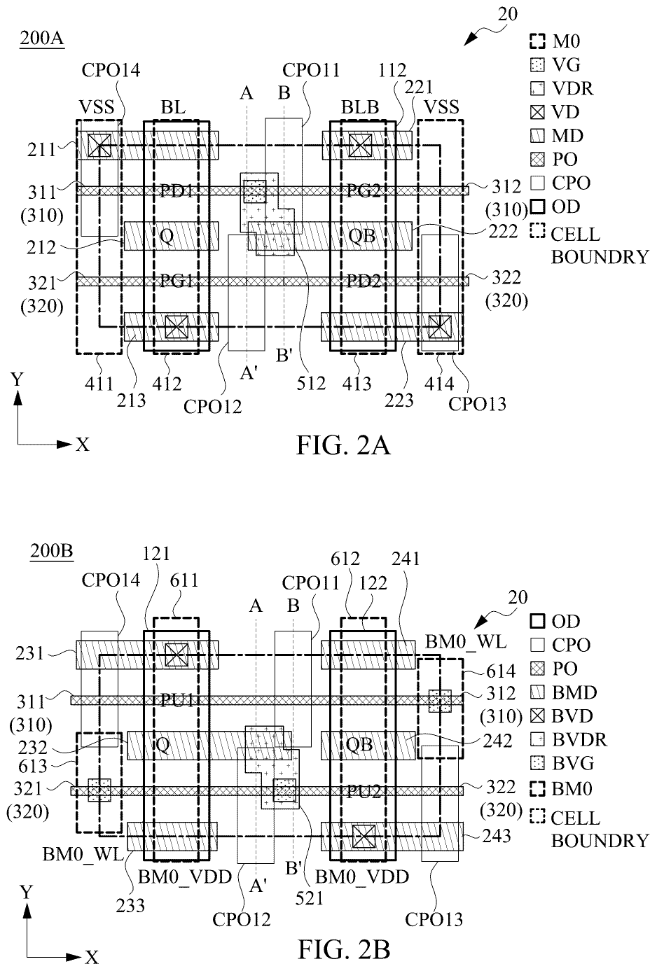

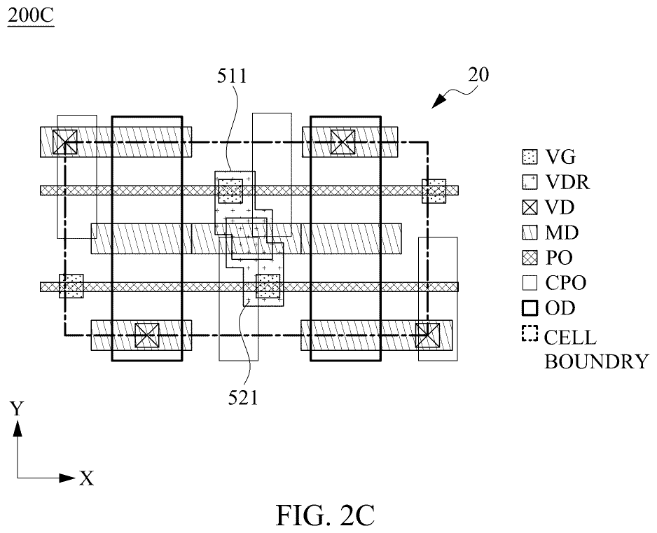

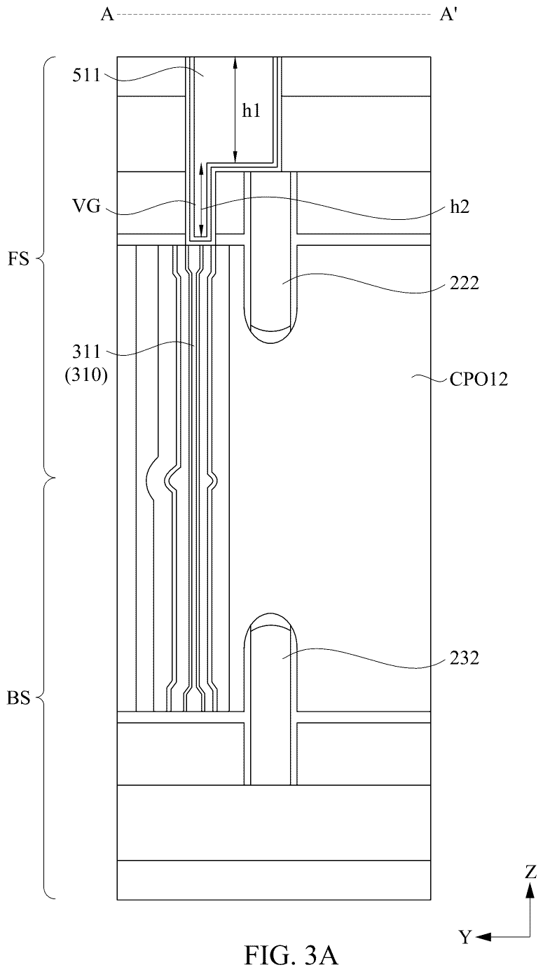

Reference is now made to FIGS. 2A and 2B. FIG. 2A is a layout diagram 200A of a front side FS of an integrated circuit 20 corresponding to the memory device 10 of FIG. 1, and FIG. 2B is a layout diagram 200B of a back side BS of the integrated circuit 20 corresponding to FIG. 2A, in accordance with some embodiments. In some embodiments, the memory device 10 is formed in the integrated circuit 20.

As illustratively shown in FIGS. 2A and 2B, the integrated circuit 20 includes the pull down transistors PD1 and PD2 and the pass gate transistors PG1 and PG2 of FIG. 1 that are disposed in a first semiconductor level, and further the pull up transistors PU1 and PU2 of FIG. 1 disposed in a second semiconductor level. In some embodiments, the first semiconductor level is different from and above the second semiconductor level along a vertical (z) direction. Alternatively stated, the pull down transistor PD1 is arranged above the pull up transistor PU1. The pull down transistor PD2 is arranged above the pull up transistor PU2.

In the layout diagram 200A of FIG. 2A, the integrated circuit 20 includes active areas (e.g., Oxide diffusion (OD)) 111-112, conductive segments (e.g., metal-on-device (MD)) 211-213 and 221-223, a gate structure 310 (e.g., polysilicon (PO)) having two structures 311-312, a gate structure 320 having two structures 321-322, conductive rails 411-414 (e.g., metal-zero layer (MO)), a connection structure (VDR) 511, and vias VG and VD that are coupling between structures in the integrated circuit 20.

In some embodiments, the active areas 111-112 are disposed in a first layer and extending in y direction. In some embodiments, the active areas 111 and 112 are doped with n-type dopants, including, such as phosphorus, arsenic, or a combination thereof.

The conductive segments 211-213 are disposed in a second layer above the first layer and over the active area 111. The conductive segments 221-223 are disposed in a second layer above the first layer and over the active area 112.

The conductive rails 411-414 extend in y direction in a third layer above the second layer. In some embodiments, the conductive rails 411 and 414 are configured to transmit a supply voltage VSS to the integrated circuit 20. The conductive rail 412 corresponds to the bit line BL of FIG. 1 and the conductive rail 413 corresponds to the bit line BLB of FIG. 1.

The gate structures 311 and 312 align each other in x direction and are separated from each other by a spacing structure CPO11. The gate structures 321 and 322 align each other in the x direction and are separated from each other by a spacing structure CPO12, in which the spacing structures CPO11 and CPO12 are configured to electrically isolate two gate structures. As shown in FIG. 2A, the spacing structures CPO11 and CPO12 stagger from each other along y direction. Moreover, the gate structures 311 and 321 pass through the active area 111. The gate structures 312 and 322 pass through the active area 112.

With reference to both FIGS. 2A and 2B, the gate structures 311-312 and 321-322 further extend in z direction to pass from the first semiconductor level to the second semiconductor level. Accordingly, in some embodiments, the gate structure 311 is shared by the pull down transistor PD1 and the pull up transistor PU1 and corresponds to gate terminals thereof. The gate structure 322 is shared by the pull down transistor PD2 and the pull up transistor PU2 and corresponds to gate terminals thereof.

In some embodiments, the gate structure 312 corresponds to a gate terminal of the pass gate transistor PG2, and the gate structure 321 corresponds to a gate terminal of the pass gate transistor PG1.

The conductive segment 211 corresponds to a source/drain terminal of the pull down transistor PD1 and configured to receive the supply voltage VSS from the conductive rail 411 through a via VD. The conductive segment 212 is shared by the pull down transistor PD1 and the pass gate transistor PG1 and corresponds to the node Q of FIG. 1. The conductive segment 213 corresponds to a drain/source terminal of the pass gate transistor PG1 and is coupled to the conductive rail 412 (corresponding to the bit line BL) through a via VD.

The conductive segment 221 corresponds to a drain/source terminal of the pass gate transistor PG2 and is coupled to the conductive rail 413 (corresponding to the bit line BLB) through a via VD. The conductive segment 222 is shared by the pull down transistor PD2 and the pass gate transistor PG2 and corresponds to the node QB of FIG. 1. The conductive segment 223 corresponds to a source/drain terminal of the pull down transistor PD2 and configured to receive the supply voltage VSS from the conductive rail 414 through a via VD.

The connection structure 511 is arranged in the first semiconductor level and on a front side of the integrated circuit 20. In some embodiments, the connection structure 511 is a layer above the structures of the pull down transistors PD1-PD2 and the pass gate transistors PG1-PG2. For example, the connection structure 511 is above layers where the active areas 111-112, the conductive segments 211-213, 221-223, and the gate structures 311-312, 321-322 are.

As shown in FIG. 2A, the connection structure 511 is of a zig-zag shape, and disposed between and separated from the active areas 111 and 112 in the layout diagram 200A. Alternatively stated, the connection structure 511 is arranged between the pair of the pull down transistor PD1 and the pass gate transistor PG1 and the pair of the pull down transistor PD2 and the pass gate transistor PG2 in the layout view.

In some embodiments, the connection structure 511 is coupled to the gate 311 through a via VG and further couples the gate structure 311 to the conductive segment 222.

In the layout diagram 200B of FIG. 2B, the integrated circuit 20 includes active areas 121-122, conductive segments (e.g., back side metal-on-device (BMD)) 231-233 and 241-243, a connection structure (e.g., BVDR) 521, conductive lines 611-614 (e.g., back side metal-zero layer (BMO)), and vias BVG and BVD that are coupling between structures in the integrated circuit 20.

In some embodiments, the active areas 121-122 extend in y direction and are disposed in a layer below where the active areas 111-112 are. In some embodiments, the active areas 121 and 122 are doped with p-type dopants including, such as boron, indium, aluminum, gallium, or a combination thereof.

The conductive segments 231-233 are arranged below the active area 121 along the z direction. The conductive segments 241-243 are arranged below the active area 122 along the z direction.

The conductive lines 611-614 extend in y direction below the conductive segments 231-233 and 241-243. In some embodiments, the conductive lines 611-614 are on a back side of the integrated circuit 20. In the layout diagram 200B of FIG. 2B, the conductive line 611 overlaps the active area 121, and the conductive line 612 overlaps the active area 122.

In some embodiments, the conductive lines 611 and 612 are configured to transmit the supply voltage VDD to the pull up transistors PU1-PU2. The integrated circuit 20. The conductive lines 613-614 correspond to the word line WL of FIG. 1 and are coupled to the pass gate transistor PG1 through the gate structure 321 and coupled to the pass gate transistor PG2 through the gate structure 312.

As shown in FIG. 2B, the gate structures 311 and 321 further pass through the active area 121. The gate structures 312 and 322 pass through the active area 122.

The conductive segment 231 corresponds to a source/drain terminal of the pull down transistor PU1 and configured to receive the supply voltage VDD from the conductive line 611 through a via BVD. The conductive segment 232 corresponds to the node Q of FIG. 1.

The conductive segment 242 corresponds to the node QB of FIG. 1. The conductive segment 243 corresponds to a source/drain terminal of the pull down transistor PU2 and configured to receive the supply voltage VDD from the conductive line 612 through a via BVD.

The connection structure 521 is arranged in the second semiconductor level and on the back side of the integrated circuit 20. In some embodiments, the connection structure 521 is below the structures of the pull up transistors PU1-PU2. For example, the connection structure 521 is below layers where the active areas 121-122, the conductive segments 231-233, 241-243, and the gate structures 311-312, 321-322 are.

As shown in FIG. 2B, the connection structure 521 is of a zig-zag shape, and disposed between and separated from the active areas 121 and 122 in the layout diagram 200A. Alternatively stated, the connection structure 521 is arranged between the pull up transistors PU1 and PU2 in the layout view.

In some embodiments, the connection structure 521 is coupled to the gate structure 322 through a via VG and further couples the gate structure 322 to the conductive segment 232.

Reference is now made to FIG. 2C. FIG. 2C is a layout diagram 200C of including part of the front side and the back side of the integrated circuit corresponding to FIG. 2A, in accordance with some embodiments. As shown in FIG. 2C, the connection structure 511 and the connection structure 521 overlap with each other in the layout view.

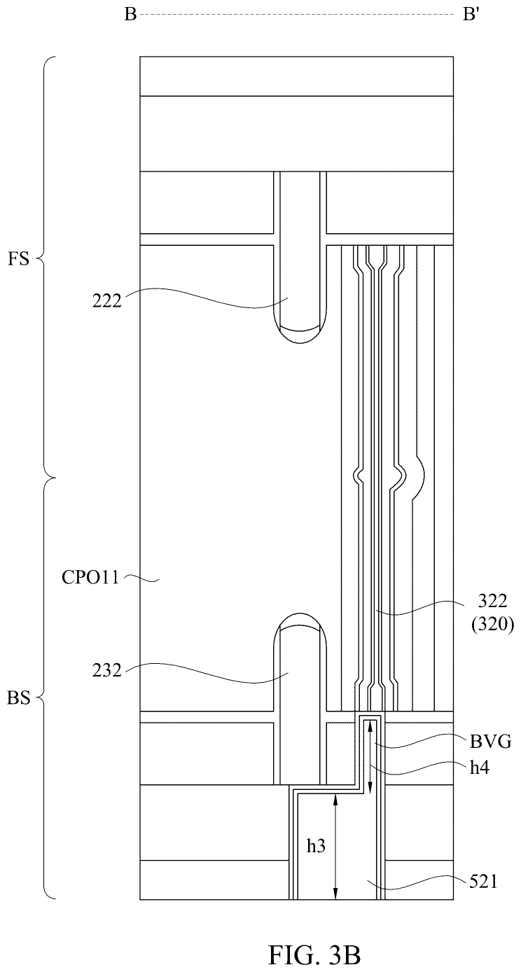

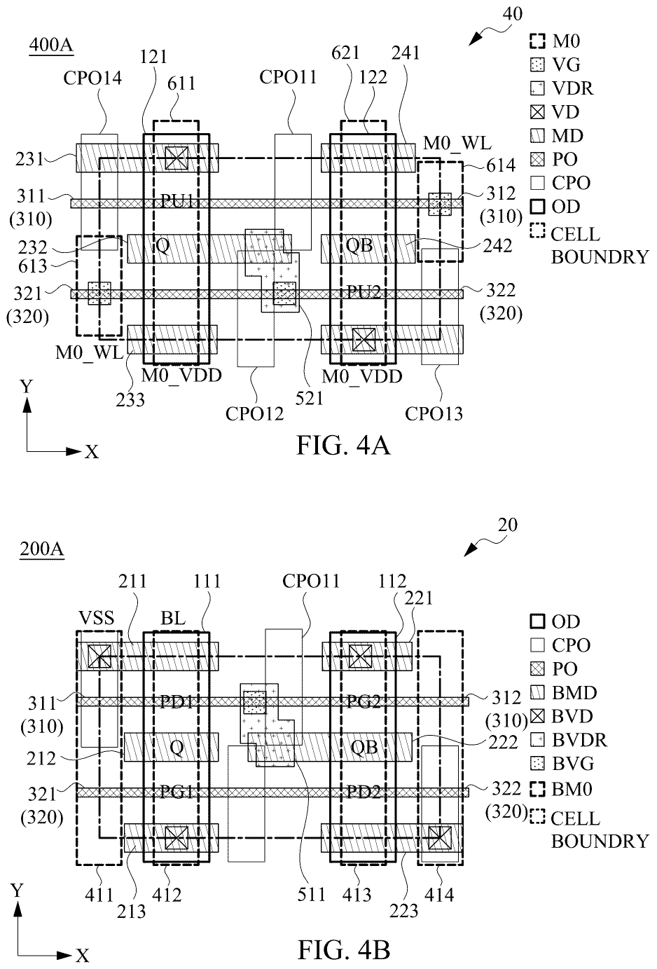

Reference is now made to FIG. 3A. FIG. 3A is a cross-sectional view of the integrated circuit corresponding to FIGS. 2A and 2B along line AA′, in accordance with some embodiments.

As illustratively shown in FIG. 3A, the connection structure 511 is on the front side of the integrated circuit 20 and arranged above the via VG and the conductive segments 222 and 232, and further electrically couples the via VG to the conductive segment 222. In some embodiments, the connection structure 511, the via VG, and the conductive segment 222 are disposed in dielectric layers extending along the y direction of FIG. 3A. The spacing structure CPO12 separates the conductive segments 222 and 232 from the gate structure 311. In some embodiments, a height h1 of the connection structure 511 along the z (vertical) direction is greater than a height h2 of the via VG.

Reference is now made to FIG. 3B. FIG. 3B is a cross-sectional view of the integrated circuit corresponding to FIGS. 2A and 2B along line BB′, in accordance with some embodiments.

As illustratively shown in FIG. 3B, the connection structure 521 is on the back side of the integrated circuit 20 and arranged below the via BVG and the conductive segments 222 and 232, and further electrically couples the via BVG to the conductive segment 232. In some embodiments, the connection structure 521, the via BVG, and the conductive segment 232 are disposed in dielectric layers extending along the y direction of FIG. 3B. The spacing structure CPO11 separates the conductive segments 222 and 232 from the gate structure 322. In some embodiments, a height h3 of the connection structure 521 along the z (vertical) direction is greater than a height h4 of the via VG.

In some embodiments, the front side of the integrated circuit 20 is referred to as structures viewed from the top and includes metal routing arranged above active semiconductor devices (i.e., with drain/source structure implements with active areas, gate structures, metal-on-device MD on the active areas, etc.) The back side of the integrated circuit 20 is referred to as structures viewed from the bottom side. In a cross-section view, for example, in FIGS. 3A-3B, metal routing on the backside are arranged under active semiconductor devices (i.e., with drain/source structure implements with active areas, gate structures, metal-on-device MD on the active areas, etc.)

In some embodiments, the active semiconductor device on the front side of the integrated circuit 20 is formed on a substrate (not shown) in a first process. After the first side process is complete, the integrated circuit 20 is flipped upside down, such that a backside surface of the substrate faces upwards. The substrate is further thinned down and removed. In some embodiments, thinning is accomplished by a CMP process, a grinding process, or the like. Accordingly, the second process is performed to form structures on the backside of the integrated circuit 20.

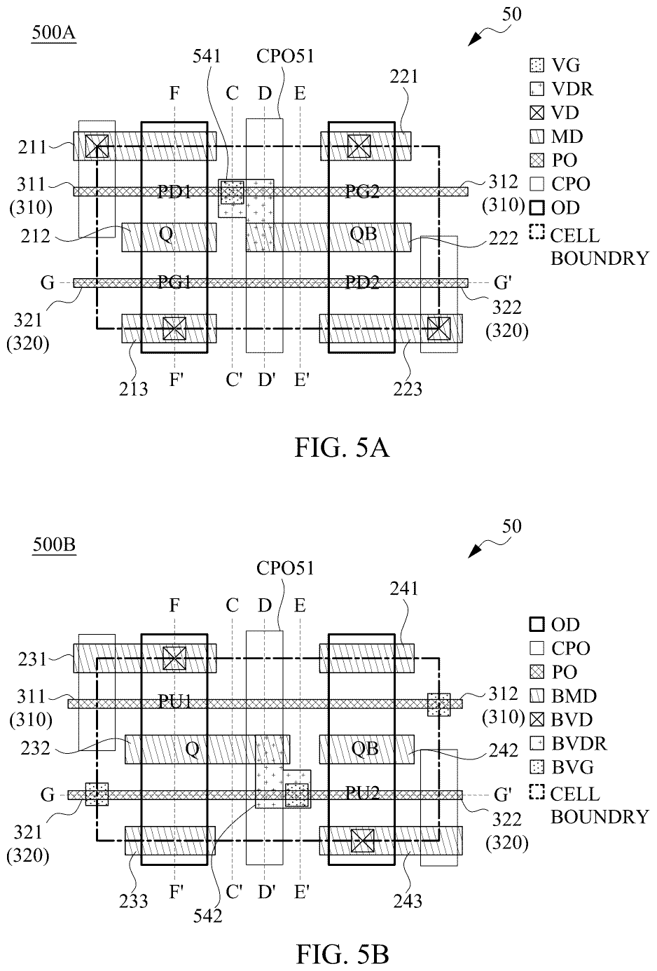

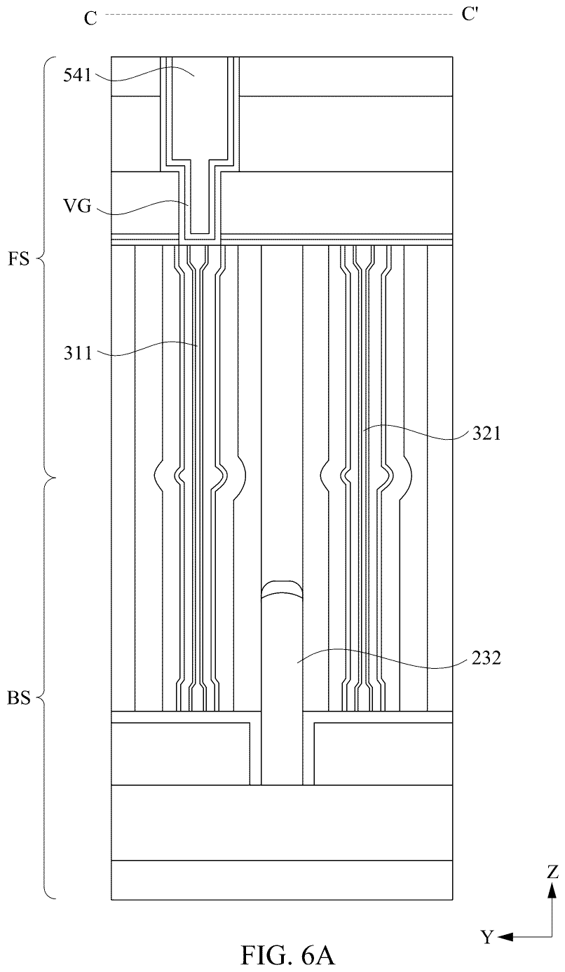

Reference is now made to FIGS. 4A and 4B. FIG. 4A is a layout diagram 400A of a front side of an integrated circuit 40 corresponding to the memory device 10 of FIG. 1, and FIG. 4B is a layout diagram 400B of a back side of the integrated circuit 40 corresponding to FIG. 4A, in accordance with some embodiments. With respect to the embodiments of FIGS. 1 to 3B, like elements in FIGS. 4A and 4B are designated with the same reference numbers for ease of understanding. The specific operations of similar elements, which are already discussed in detail in above paragraphs, are omitted herein for the sake of brevity.

In some embodiments, the integrated circuit 40 is configured with respect to, for example, the integrated circuit 20 of FIGS. 2A to 3B. Compared with the integrated circuit 20 of FIGS. 2A to 3B, the pull up transistors PU1 and PU2 of the integrated circuit 40 are disposed in the first semiconductor level while the pass gate transistors PG1-PG2 and the pull down transistors PD1-PD2 are disposed in the second semiconductor level and below the pull up transistors PU1-PU2.

Specifically, the conductive segments 231-233 are arranged above the active area 121, and the conductive segments 241-243 are arranged above the active area 122. The conductive segment 231 is coupled to the conductive line 611 while the conductive line 611 is above the conductive segments 231-233. The conductive segment 243 is coupled to the conductive line 612 while the conductive line 612 is above the conductive segments 241-243. In some embodiments, the conductive lines 611-614 are metal-zero layers on the front side of the integrated circuit 40.

The connection structure 521 is arranged above the conductive segment 232 and the gate structure 322, and couples the conductive segments 232 to the gate structure 322.

With reference to FIG. 4B, the conductive segments 211-213 are arranged below the active area 111, and the conductive segments 221-223 are arranged below the active area 112. The conductive segments 211 and 213 are coupled to the conductive rails 411 and 412 respectively while the conductive rails 411 and 412 are below the conductive segments 211-213. The conductive segments 221 and 223 are coupled to the conductive rails 413 and 414 respectively while the conductive rails 413 and 414 are below the conductive segments 221-223. In some embodiments, the conductive rails 411-413 are backside metal-zero layers on the back side of the integrated circuit 40.

The connection structure 511 is arranged below the conductive segment 222 and the gate structure 311, and couples the conductive segments 222 to the gate structure 311.

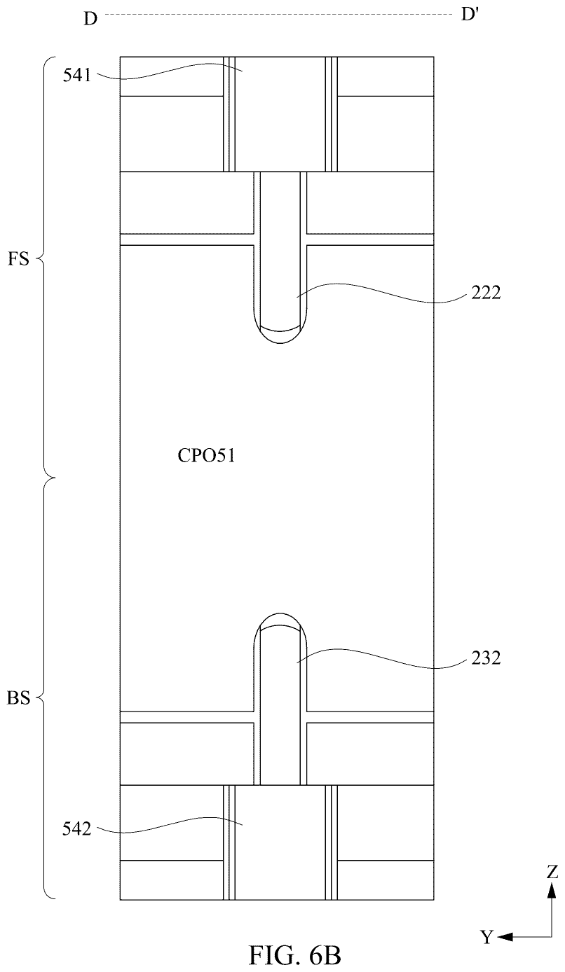

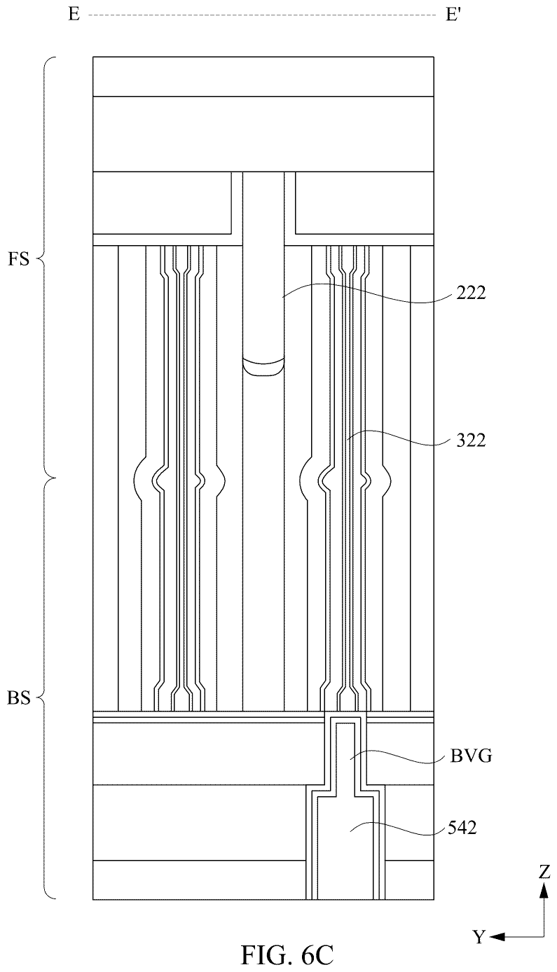

Reference is now made to FIGS. 5A and 5B. FIG. 5A is a layout diagram 500A of a front side of an integrated circuit 50 corresponding to the memory device 10 of FIG. 1, and FIG. 5B is a layout diagram 500B of a back side of the integrated circuit 50 corresponding to FIG. 4A, in accordance with some embodiments. With respect to the embodiments of FIGS. 1 to 4B, like elements in FIGS. 5A and 5B are designated with the same reference numbers for ease of understanding. The specific operations of similar elements, which are already discussed in detail in above paragraphs, are omitted herein for the sake of brevity.

In some embodiments, the integrated circuit 50 is configured with respect to, for example, the integrated circuit 20 of FIGS. 2A to 3B. Compared with the integrated circuit 20 of FIGS. 2A to 3B, instead of having connection structure of zig-zag shape, the integrated circuit 50 includes L-shape connection structures 541 and 542.

In some embodiments, the connection structure 541 is configured with respect to, for example, the connection structure 511 of FIG. 2A and couples the gate structure 311 to the conductive segment 222. The connection structure 542 is configured with respect to, for example, the connection structure 521 of FIG. 2B and couples the gate structure 322 to the conductive segment 232.

Furthermore, the gate structures 311 and 312 are separated from each other by a region defined by a spacing structure CPO51 that extends straightly in y direction. Similarly, the gate structures 321 and 322 are separated from the spacing structure CPO51.

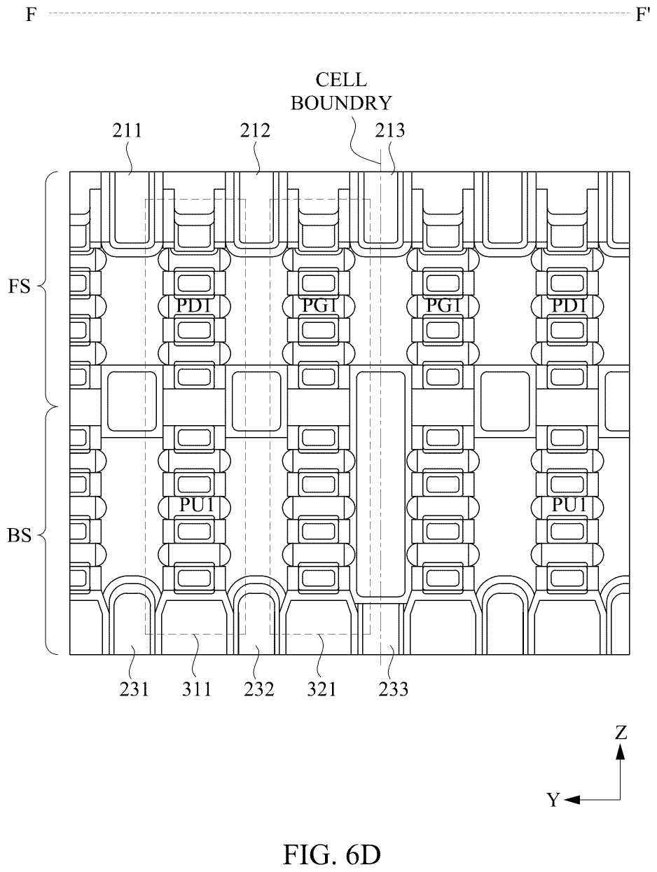

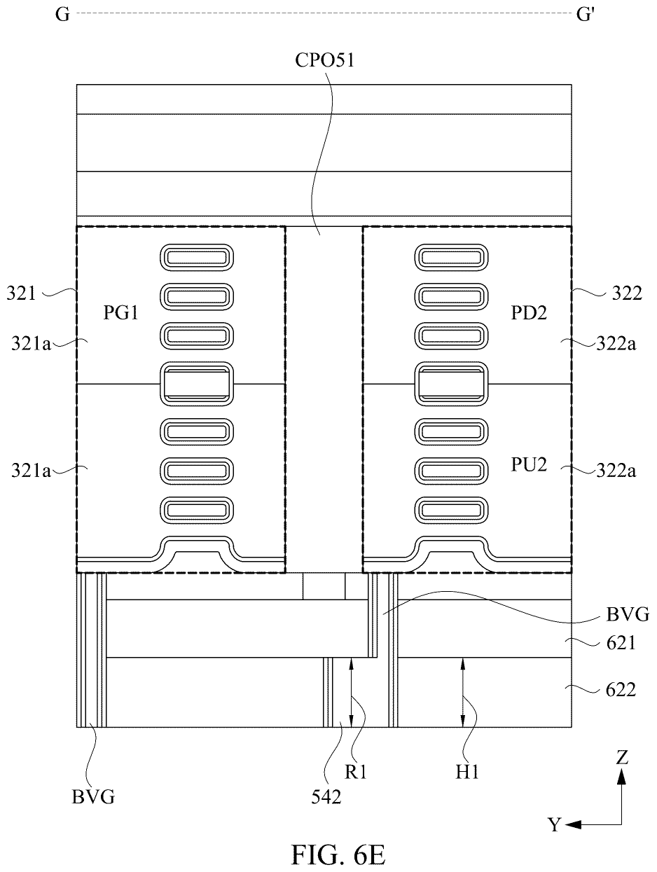

Reference is now made to FIGS. 6A to 6E. FIG. 6A to FIG. 6E are cross-sectional diagrams of the integrated circuit 50 corresponding to FIGS. 5A and 5B along lines CC′, DD′, EE′, FF′ and GG′ separately, in accordance with some embodiments.

With reference to FIGS. 5A, 5B, and 6A together, the connection structure 541 is on the front side of the integrated circuit 50 and arranged above the via VG. The connection structure 541 further electrically couples to the via VG and the gate structure 311. In some embodiments, the connection structure 541, the via VG, and the conductive segment 232 are disposed in dielectric layers extending along the y direction of FIG. 6A.

In FIG. 6B shown the cross-section diagram along the line DD′ of FIGS. 5A and 5B, the spacing structure CPO51 separates the conductive segments 222 and 232 from the gate structure 311. The connection structure 541 is connected to the conductive segment 222. The connection structure 542 is connected to the conductive segment 232.

In FIG. 6C shown the cross-section diagram along the line EE′ of FIGS. 5A and 5B, the connection structure 542 is on the back side of the integrated circuit 50 and arranged below the via BVG. The connection structure 542 further electrically couples to the via BVG and the gate structure 322. In some embodiments, the connection structure 542, the via BVG, and the conductive segment 222 are disposed in dielectric layers extending along the y direction of FIG. 6C.

For structures of the active areas and gate structures, as shown in FIG. 6D, the gate structure 311 is shared by the pull down transistor PD1 and pull up transistor PU.

Specifically, in FIG. 6E, the gate structure 321 includes metal gate portion 321a that is on the front side and corresponds to the pass gate transistor PG1 and metal gate portion 321b that is on the backside and electrically connected to the metal gate portion 321a. The via BVG is electrically to the gate structure 321 for transmitting the word line signal to the gate structure 321.

The gate structure 322 includes metal gate portion 322a that is on the front side and corresponds to the pull down transistor PD2 and metal gate portion 322b that is on the backside, corresponds to the pull up transistor PU2, and electrically connected to the metal gate portion 322a. The via BVG is electrically to the gate structure 321 for transmitting the word line signal to the gate structure 321.

Moreover, the via BVG has a first surface contacts the gate structure 322 and a second surface that is opposing the first surface and couples to the connection structure 542. The connection structure 542 has a first surface contacting a dielectric layer 621 surrounding the via BVG and a second surface opposing the first surface. The connection structure 542 is surrounded by a dielectric layer 622 below the dielectric layer 621. In some embodiments, the height R1 between the first and second surfaces of the connection structure 542 is equal to a height H1 of the dielectric layer 622. As shown in FIG. 6E, a height of the BVG that couples to the gate structure 321 is greater than the height R1.

Reference is now made to FIG. 6F. FIG. 6F is a cross-sectional diagram of the integrated circuit 50 along the line GG′ according to an embodiment different from FIG. 6E.

As shown in FIG. 6F, a height R2 between the first and second surfaces of the connection structure 542 is smaller than the height H1 of the dielectric layer 622 along z direction. The via BVG that couples to the pull up transistor PU2 has a height greater than the height R2 of the connection structure 542 and equal to that of the via BVG couples to the pass gate transistor PG1. Alternatively stated, the second surface of the via BVG that couples to the pull up transistor PU2 is aligned to a surface of the via BVG that couples to the pass gate transistor PG1 along y direction, and is misaligned to the second surface of the second connection structure 542.

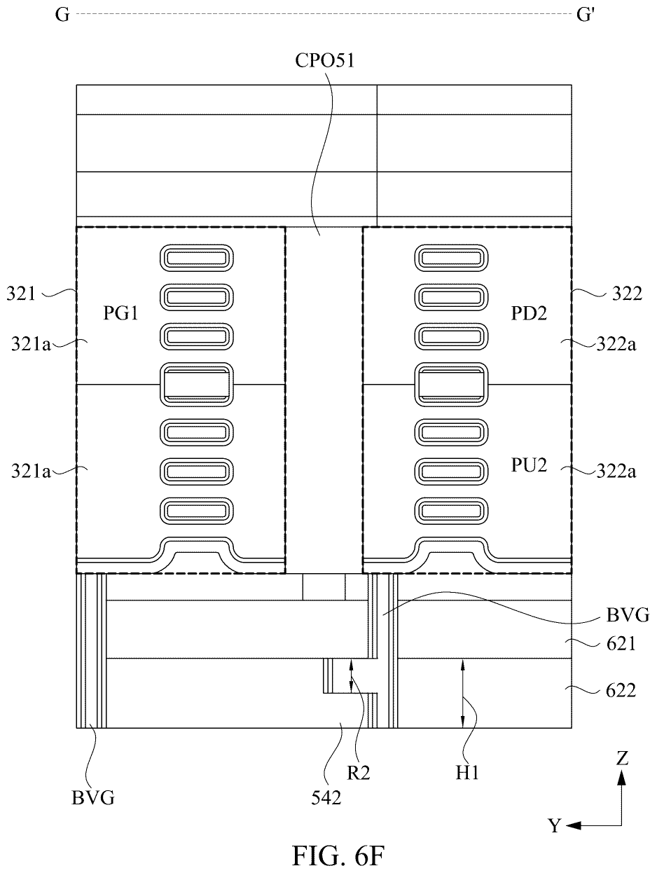

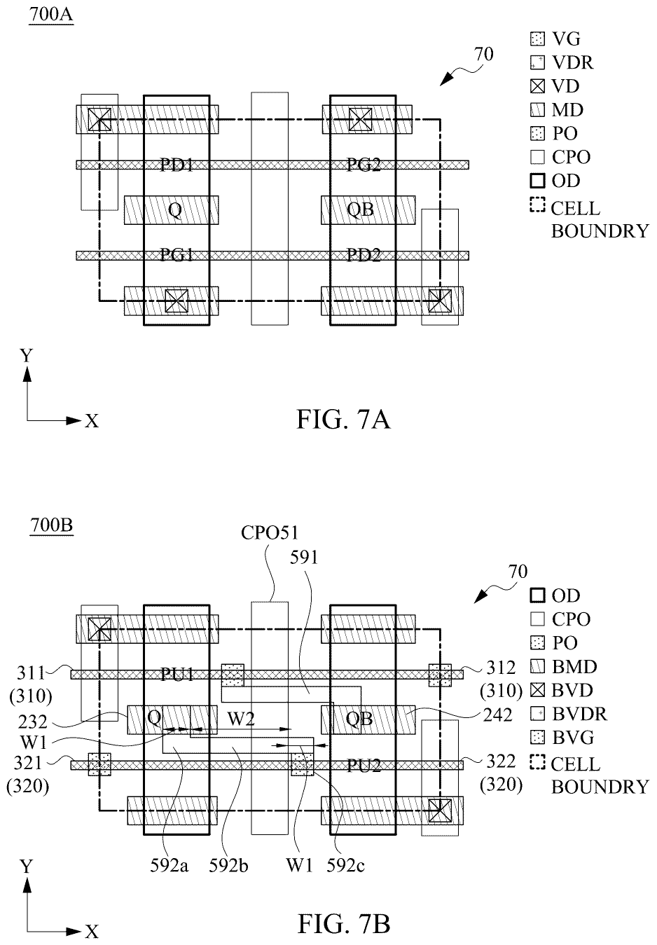

Reference is now made to FIGS. 7A and 7B. FIG. 7A is a layout diagram 700A of a front side of an integrated circuit 70 corresponding to the memory device 10 of FIG. 1, and FIG. 7B is a layout diagram 700B of a back side of the integrated circuit 70 corresponding to FIG. 7A, in accordance with some embodiments. With respect to the embodiments of FIGS. 1 to 6F, like elements in FIGS. 7A and 7B are designated with the same reference numbers for ease of understanding. The specific operations of similar elements, which are already discussed in detail in above paragraphs, are omitted herein for the sake of brevity.

Compared with the embodiments of FIGS. 2A-2B, the integrated circuit 70 includes connection structures 591 and 592 on the backside of the integrated circuit 70. Specifically, the connection structure 591 is arranged below the gate structure 311 and the conductive segment 242, and configured to couple the gate structure 311 to the conductive segment 242 through a via BVG. The connection structure 592 is arranged below the gate structure 322 and the conductive segment 232, and configured to couple the gate structure 322 to the conductive segment 232 through a via BVG, as shown in FIG. 7B.

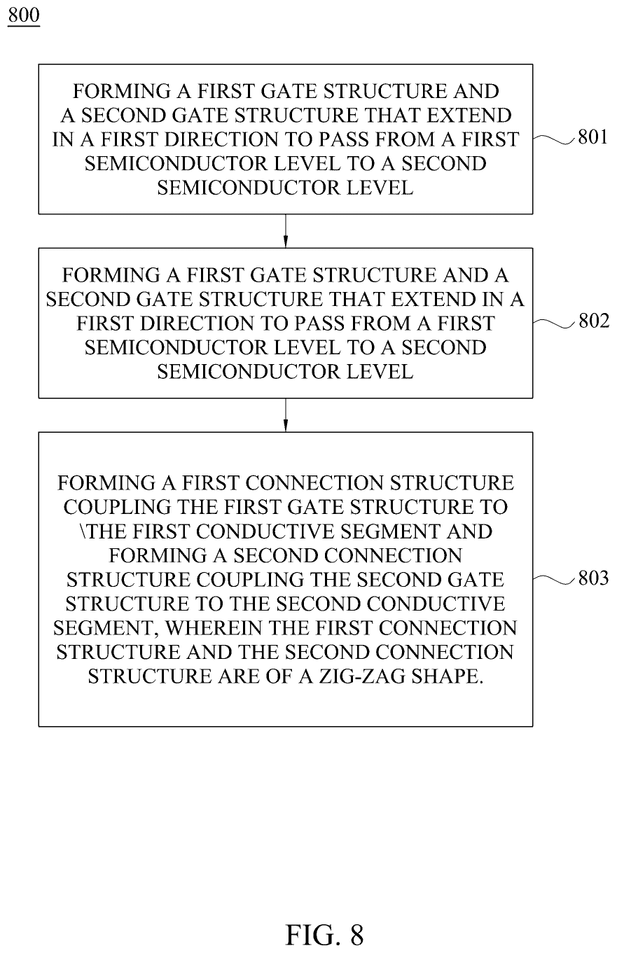

FIG. 8 is a flow chart of a method 800 of manufacturing an integrated circuit, in accordance with some embodiments. It is understood that additional operations can be provided before, during, and after the processes shown by FIG. 8, and some of the operations described below can be replaced or eliminated, for additional embodiments of the method. The order of the operations/processes may be interchangeable. Throughout the various views and illustrative embodiments, like reference numbers are used to designate like elements. The method 800 has operations 801-803 and will be discussed with reference to embodiments of FIG. 1 to FIG. 7B.

In operation 801, as shown in FIGS. 2A-6F, the gate structure 311 and the gate structure 322 extend in z direction are formed to pass from the first semiconductor level (e.g., where the pull down transistors PD1-PD2 and the pass gate transistors PG1-PG2 are) to the second semiconductor level (e.g., where the pull up transistors PU1-PU2 are.)

In operation 802, for example, in FIG. 7B, the conductive segment 242 and the conductive segment 232 are formed. The conductive segment 242 is disposed diagonally to the gate structure 311, and the conductive segment 232 is disposed diagonally to the gate structure 322.

In operation 803, the connection structure 591 coupling the gate structure 311 to the conductive segment 242 is formed and the connection structure 592 coupling the gate structure 322 to the conductive segment 232. The connection structure 591 and the connection structure 592 are of a zig-zag shape.

In some embodiments, forming the connection structure 592 further includes operation of forming a first portion 592a having a width W1, forming a second portion 592b having a width W2 greater than the width W1 along x direction, and forming a third portion 592c having the width W1.

The connection structure 591 is configured with respect to, for example, the connection structure 592. The configurations of forming three parts of the connection structure 591 are similar to those of the connection structure 592. Hence, the repetitious descriptions are omitted here.

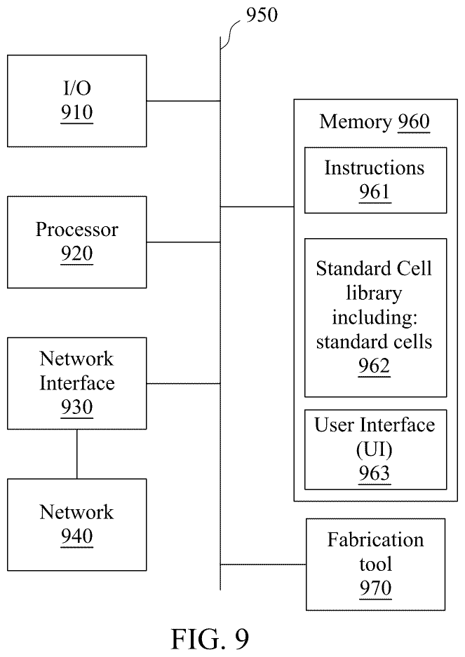

Reference is now made to FIG. 9. FIG. 9 is a block diagram of an electronic design automation (EDA) system 900 for designing the integrated circuit layout design, in accordance with some embodiments of the present disclosure. EDA system 900 is configured to implement one or more operations of the method 800 disclosed in FIG. 8, and further explained in conjunction with FIGS. 1-7B. In some embodiments, EDA system 900 includes an APR system.

In some embodiments, EDA system 900 is a general purpose computing device including a hardware processor 920 and a non-transitory, computer-readable storage medium 960. Storage medium 960, amongst other things, is encoded with, i.e., stores, computer program code (instructions) 961, i.e., a set of executable instructions. Execution of instructions 961 by hardware processor 920 represents (at least in part) an EDA tool which implements a portion or all of, e.g., the method 800.

The processor 920 is electrically coupled to computer-readable storage medium 960 via a bus 950. The processor 920 is also electrically coupled to an I/O interface 910 and a fabrication tool 970 by bus 950. A network interface 930 is also electrically connected to processor 920 via bus 950. Network interface 930 is connected to a network 940, so that processor 920 and computer-readable storage medium 960 are capable of connecting to external elements via network 940. The processor 920 is configured to execute computer program code 961 encoded in computer-readable storage medium 960 in order to cause EDA system 900 to be usable for performing a portion or all of the noted processes and/or methods. In one or more embodiments, processor 920 is a central processing unit (CPU), a multi-processor, a distributed processing system, an application specific integrated circuit (ASIC), and/or a suitable processing unit.

In one or more embodiments, computer-readable storage medium 960 is an electronic, magnetic, optical, electromagnetic, infrared, and/or a semiconductor system (or apparatus or device). For example, computer-readable storage medium 960 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 960 includes a compact disk-read only memory (CD-ROM), a compact disk-read/write (CD-R/W), and/or a digital video disc (DVD).

In one or more embodiments, storage medium 960 stores computer program code 961 configured to cause EDA system 900 (where such execution represents (at least in part) the EDA tool) to be usable for performing a portion or all of the noted processes and/or methods. In one or more embodiments, storage medium 960 also stores information which facilitates performing a portion or all of the noted processes and/or methods. In one or more embodiments, storage medium 960 stores library 962 of standard cells including such standard cells as disclosed herein, for example, a cell including transistors PD1-PD2, PG1-PG2, and PU1-PU2.

EDA system 900 includes I/O interface 910. I/O interface 910 is coupled to external circuitry. In one or more embodiments, I/O interface 910 includes a keyboard, keypad, mouse, trackball, trackpad, touchscreen, and/or cursor direction keys for communicating information and commands to processor 920.

EDA system 900 also includes network interface 930 coupled to processor 920. Network interface 930 allows EDA system 900 to communicate with network 940, to which one or more other computer systems are connected. Network interface 930 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 900.

EDA system 900 also includes the fabrication tool 970 coupled to processor 920. The fabrication tool 970 is configured to fabricate integrated circuits, e.g., the memory device 10 of FIG. 1 and the integrated circuits 20, 40, 50, 70 illustrated in FIGS. 2A-7B, according to the design files processed by the processor 920.

EDA system 900 is configured to receive information through I/O interface 910. The information received through I/O interface 910 includes one or more of instructions, data, design rules, libraries of standard cells, and/or other parameters for processing by processor 920. The information is transferred to processor 920 via bus 950. EDA system 900 is configured to receive information related to a UI through I/O interface 910. The information is stored in computer-readable medium 960 as user interface (UI) 963.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 900. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, for example, one or more of an optical disk, such as a DVD, a magnetic disk, such as a hard disk, a semiconductor memory, such as a ROM, a RAM, a memory card, and the like.

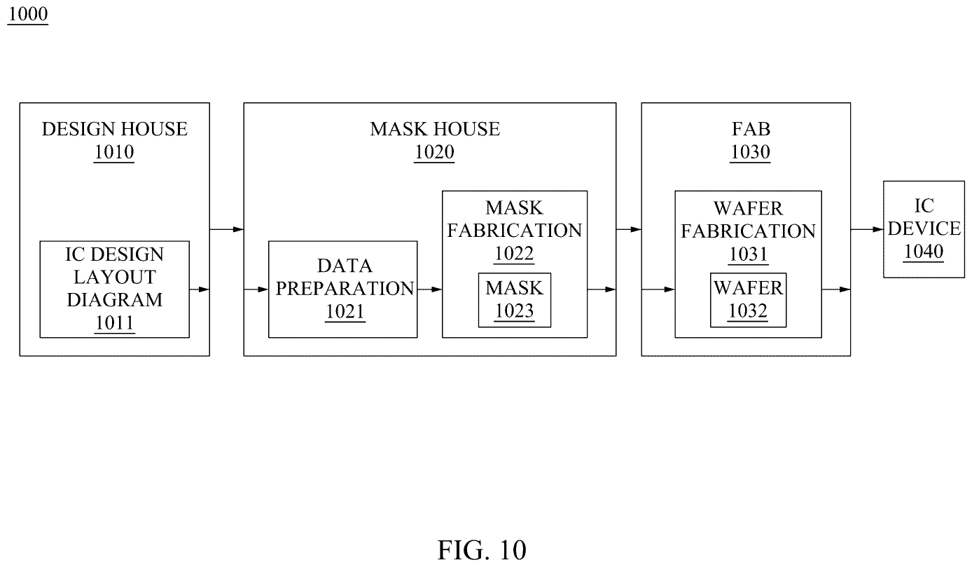

FIG. 10 is a block diagram of IC manufacturing system 1000, and an IC manufacturing flow associated therewith, in accordance with some embodiments. In some embodiments, based on a layout diagram, at least one of (A) one or more semiconductor masks or (B) at least one component in a layer of a semiconductor integrated circuit is fabricated using IC manufacturing system 1000.

In FIG. 10, IC manufacturing system 1000 includes entities, such as a design house 1010, a mask house 1020, and an IC manufacturer/fabricator (“fab”) 1030, that interact with one another in the design, development, and manufacturing cycles and/or services related to manufacturing an IC device 1040. The entities in IC manufacturing system 1000 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1010, mask house 1020, and IC fab 1030 is owned by a single larger company. In some embodiments, two or more of design house 1010, mask house 1020, and IC fab 1030 coexist in a common facility and use common resources.

Design house (or design team) 1010 generates an IC design layout diagram 1011. IC design layout diagram 1011 includes various geometrical patterns, for example, an IC layout design depicted in FIGS. 2A-7B, designed for an IC device 1040, for example, integrated circuits 20, 40, 50, 70, discussed above with respect to FIGS. 2A-7B. The geometrical patterns correspond to patterns of metal, oxide, or semiconductor layers that make up the various components of IC device 1040 to be fabricated. The various layers combine to form various IC features. For example, a portion of IC design layout diagram 1011 includes various IC features, such as an active region, gate electrode, source and drain, conductive segments or vias of an interlayer interconnection, to be formed in a semiconductor substrate (such as a silicon wafer) and various material layers disposed on the semiconductor substrate. Design house 1010 implements a proper design procedure to form IC design layout diagram 1011. The design procedure includes one or more of logic design, physical design or place and route. IC design layout diagram 1011 is presented in one or more data files having information of the geometrical patterns. For example, IC design layout diagram 1011 can be expressed in a GDSII file format or DFII file format.

Mask house 1020 includes data preparation 1021 and mask fabrication 1022. Mask house 1020 uses IC design layout diagram 1011 to manufacture one or more masks 1023 to be used for fabricating the various layers of IC device 1040 according to IC design layout diagram 1011. Mask house 1020 performs mask data preparation 1021, where IC design layout diagram 1011 is translated into a representative data file (“RDF”). Mask data preparation 1021 provides the RDF to mask fabrication 1022. Mask fabrication 1022 includes a mask writer. A mask writer converts the RDF to an image on a substrate, such as a mask (reticle) 1023 or a semiconductor wafer 1032. The IC design layout diagram 1011 is manipulated by mask data preparation 1021 to comply with particular characteristics of the mask writer and/or requirements of IC fab 1030. In FIG. 10, data preparation 1021 and mask fabrication 1022 are illustrated as separate elements. In some embodiments, data preparation 1021 and mask fabrication 1022 can be collectively referred to as mask data preparation.

In some embodiments, data preparation 1021 includes optical proximity correction (OPC) which uses lithography enhancement techniques to compensate for image errors, such as those that can arise from diffraction, interference, other process effects and the like. OPC adjusts IC design layout diagram 1011. In some embodiments, data preparation 1021 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, data preparation 1021 includes a mask rule checker (MRC) that checks the IC design layout diagram 1011 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1011 to compensate for limitations during mask fabrication 1022, which may undo part of the modifications performed by OPC in order to meet mask creation rules.

In some embodiments, data preparation 1021 includes lithography process checking (LPC) that simulates processing that will be implemented by IC fab 1030 to fabricate IC device 1040. LPC simulates this processing based on IC design layout diagram 1011 to create a simulated manufactured device, such as IC device 1040. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 1011.

It should be understood that the above description of data preparation 1021 has been simplified for the purposes of clarity. In some embodiments, data preparation 1021 includes additional features such as a logic operation (LOP) to modify the IC design layout diagram 1011 according to manufacturing rules. Additionally, the processes applied to IC design layout diagram 1011 during data preparation 1021 may be executed in a variety of different orders.

After data preparation 1021 and during mask fabrication 1022, a mask 1023 or a group of masks 1023 are fabricated based on the modified IC design layout diagram 1011. In some embodiments, mask fabrication 1022 includes performing one or more lithographic exposures based on IC design layout diagram 1011. In some embodiments, an electron-beam (e-beam) or a mechanism of multiple e-beams is used to form a pattern on a mask (photomask or reticle) 1023 based on the modified IC design layout diagram 1011. Mask 1023 can be formed in various technologies. In some embodiments, mask 1023 is formed using binary technology. In some embodiments, a mask pattern includes opaque regions and transparent regions. A radiation beam, such as an ultraviolet (UV) beam, used to expose the image sensitive material layer (for example, photoresist) which has been coated on a wafer, is blocked by the opaque region and transmits through the transparent regions. In one example, a binary mask version of mask 1023 includes a transparent substrate (for example, fused quartz) and an opaque material (for example, chromium) coated in the opaque regions of the binary mask. In another example, mask 1023 is formed using a phase shift technology. In a phase shift mask (PSM) version of mask 1023, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1022 is used in a variety of processes. For example, such a mask(s) is used in an ion implantation process to form various doped regions in semiconductor wafer 1032, in an etching process to form various etching regions in semiconductor wafer 1032, and/or in other suitable processes.

IC fab 1030 includes wafer fabrication 1031. IC fab 1030 is an IC fabrication business that includes one or more manufacturing facilities for the fabrication of a variety of different IC products. In some embodiments, IC Fab 1030 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1030 uses mask(s) 1023 fabricated by mask house 1020 to fabricate IC device 1040. Thus, IC fab 1030 at least indirectly uses IC design layout diagram 1011 to fabricate IC device 1040. In some embodiments, semiconductor wafer 1032 is fabricated by IC fab 1030 using mask(s) 1023 to form IC device 1040. In some embodiments, the IC fabrication includes performing one or more lithographic exposures based at least indirectly on IC design layout diagram 1011. Semiconductor wafer 1032 includes a silicon substrate or other proper substrate having material layers formed thereon. Semiconductor wafer 1032 further includes one or more of various doped regions, dielectric features, multilevel interconnects, and the like (formed at subsequent manufacturing steps).

As described above, a method and an integrated circuit are provided in the present application. The integrated circuit includes dual side connection structures to couple each of bit nodes in a memory device to a corresponding internal node. The connection structures specifically have a shape facilitating efficiency in layout design and semiconductor manufacturing process.

In some embodiments, an integrated circuit is provided and includes a first gate structure shared by a first transistor in a first semiconductor level and a second transistor in a second semiconductor level; a first conductive segment shared by a third transistor and a fourth transistor that are disposed in the first semiconductor level; a first connection structure coupling the first gate structure to the first conductive segment on a first side of the integrated circuit; a second gate structure shared by the fourth transistor and a fifth transistor that is disposed in a second semiconductor level; a second connection structure coupled to the second gate structure and disposed on a second side, different from the first side, of the integrated circuit; and a second connection segment corresponding to a first terminal of the second transistor and coupled to the second connection structure.

In some embodiments, an integrated circuit is provided and includes a memory cell, including: a first pull down transistor and a second pull down transistor disposed in a first semiconductor level, in which the first pull down transistor includes a first gate structure corresponding to a gate terminal thereof, and the second pull down transistor includes a first conductive segment corresponding to a first node of the memory cell; a first connection structure disposed on a first side of the memory cell and coupling the first gate structure to the first conductive segment; a first pull up transistor and a second pull up transistor disposed in a second semiconductor level different from the first semiconductor level, in which the first pull up transistor includes a second conductive segment corresponding to a second node of the memory cell, and the second pull up transistor includes a second gate structure corresponding to a gate terminal thereof; and a second connection structure disposed on a second side, different from the first side, of the memory cell and coupling the second gate structure to the second conductive segment.

In some embodiments, a method is provided and includes steps as below: forming a first gate structure and a second gate structure that extend in a first direction to pass from a first semiconductor level to a second semiconductor level; forming a first conductive segment and a second conductive segment, in which the first conductive segment is disposed diagonally to the first gate structure, and the second conductive segment is disposed diagonally to the second gate structure; and forming a first connection structure coupling the first gate structure to the first conductive segment and forming a second connection structure coupling the second gate structure to the second conductive segment, in which the first connection structure and the second connection structure are of a zig-zag shape.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit, comprising:
a first gate structure shared by a first transistor in a first semiconductor level and a second transistor in a second semiconductor level;
a first conductive segment shared by a third transistor and a fourth transistor that are disposed in the first semiconductor level;
a first connection structure coupling the first gate structure to the first conductive segment on a first side of the integrated circuit;
a second gate structure shared by the fourth transistor and a fifth transistor that is disposed in the second semiconductor level;
a second connection structure coupled to the second gate structure and disposed on a second side, different from the first side, of the integrated circuit; and
a second connection segment corresponding to a first terminal of the second transistor and coupled to the second connection structure.

2. The integrated circuit of claim 1, wherein the first connection structure is of a zig-zag shape.

3. The integrated circuit of claim 1, further comprising:
a third gate structure corresponding to a gate of the third transistor, wherein the first gate structure and the third gate structure align each other in a first direction and are separated from each other by a first spacing structure; and
a fourth gate structure corresponding to a gate of a sixth transistor, wherein the fourth gate structure and the second gate structure align each other in the first direction and are separated from each other by a second spacing structure,
wherein the first spacing structure and the second spacing structure stagger from each other along a second direction different from the first direction.

4. The integrated circuit of claim 3, further comprising:
a first active area passed through by the first gate structure; and
a second active area passed through by the second gate structure,
wherein the first connection structure is disposed between and separated from the first active area and the second active area in a layout view.

5. The integrated circuit of claim 4, further comprising:
a third active area passed through by the first gate structure;
a fourth active area passed through by the second gate structure;
a first conductive line disposed on the second side of the integrated circuit and coupled to a second terminal of the second transistor; and
a second conductive line disposed on the second side of the integrated circuit and coupled to the fifth transistor,
wherein in the layout view the first conductive line overlaps the third active area and the second conductive line overlaps the fourth active area.

6. The integrated circuit of claim 1, wherein the first connection structure and the second connection structure are of a L shape.

7. The integrated circuit of claim 1, wherein the first side of the integrated circuit is a front side, and the second side of the integrated circuit is a back side.

8. A memory device, comprising:
a memory cell, comprising:
a first pull down transistor and a second pull down transistor disposed in a first semiconductor level,
wherein the first pull down transistor comprises a first gate structure corresponding to a gate terminal thereof, and the second pull down transistor comprises a first conductive segment corresponding to a first node of the memory cell;
a first connection structure disposed on a first side of the memory cell and coupling the first gate structure to the first conductive segment;
a first pull up transistor and a second pull up transistor disposed in a second semiconductor level different from the first semiconductor level,
wherein the first pull up transistor comprises a second conductive segment corresponding to a second node of the memory cell, and the second pull up transistor comprises a second gate structure corresponding to a gate terminal thereof; and
a second connection structure disposed on a second side, different from the first side, of the memory cell and coupling the second gate structure to the second conductive segment.

9. The memory device of claim 8, wherein the first connection structure is above the first pull down transistor and the second pull down transistor and arranged between the first pull down transistor and the second pull down transistor in a layout view, and
the second connection structure is below the first pull up transistor and the second pull up transistor and arranged between the first pull up transistor and the second pull up transistor in the layout view.

10. The memory device of claim 8, wherein the second connection structure is coupled to the second gate structure through a via.

11. The memory device of claim 10, wherein a height of the via is greater than a height of the second connection structure along a vertical direction.

12. The memory device of claim 10, wherein the via has a first surface contacts the second gate structure and a second surface opposing the first surface,
wherein the second connection structure has a first surface contacting a dielectric layer surrounding the via and a second surface opposing the first surface of the second connection structure,
wherein the second surface of the via is misaligned to the second surface of the second connection structure.

13. The memory device of claim 10, wherein the via has a first surface contacts the second gate structure and a second surface that is opposing the first surface and contacts the second connection structure,
wherein the second connection structure is surrounded by a first dielectric layer,
wherein the second connection structure has a first surface contacting a second dielectric layer surrounding the via and a second surface opposing the first surface of the second connection structure,
wherein a height between the first and second surfaces of the second connection structure is equal to a height of the first dielectric layer.

14. The memory device of claim 8, wherein the memory cell further comprises:
a first pass gate transistor disposed in the first semiconductor level, coupled to the first pull down transistor, and comprising a third gate structure that is separated from the second gate structure by a first spacing structure; and
a second pass gate transistor disposed in the first semiconductor level, coupled to the second pull down transistor, and comprising a fourth gate structure that is separated from the first gate structure by a second spacing structure different from the first spacing structure.

15. The memory device of claim 8, wherein the first connection structure and the second connection structure overlap with each other in a layout view.

16. A method, comprising:
forming a first gate structure and a second gate structure that extend in a first direction to pass from a first semiconductor level to a second semiconductor level;
forming a first conductive segment and a second conductive segment, wherein the first conductive segment is disposed diagonally to the first gate structure, and the second conductive segment is disposed diagonally to the second gate structure; and
forming a first connection structure coupling the first gate structure to the first conductive segment and forming a second connection structure coupling the second gate structure to the second conductive segment,
wherein the first connection structure and the second connection structure are of a zig-zag shape.

17. The method of claim 16, wherein the first connection structure and the second connection structure are on a back side of an integrated circuit.

18. The method of claim 16, wherein the first connection structure and the second connection structure are on opposite sides of an integrated circuit.

19. The method of claim 16, wherein forming the second connection structure comprises:
forming a first portion of the second connection structure having a first width in a second direction; and
forming a second portion of the second connection structure that contacts the first portion of the second connection structure and has a second width greater than the first width in the second direction.

20. The method of claim 19, wherein forming the second connection structure further comprises:
forming a third portion that contacts the second portion of the second connection structure and has the first width.
